(19) United States
(12) Patent Application Publication
(10) Pub. No.: US 2014/0063593 A1
(43) Pub. Date: Mar. 6, 2014

(54) Capacitor discharge pulse drive circuit with fast recovery

(71) Applicant: Martin Ole Berendt, Arvore (PT)

(72) Inventor: Martin Ole Berendt, Arvore (PT)

(21) Appl. No.: 13/601,644

(22) Filed: Aug. 31, 2012

(51) Int. Cl. H01S 5/042; H01S 3/067; H03K 3/57

(52) U.S. Cl. CPC H01S 5/0428; H03K 3/57; H01S 3/067
USPC 359/341.1; 372/38.02; 307/108

(57) ABSTRACT

A circuit apparatus for driving short current pulses through a laser diode is disclosed. The circuit allow fast recovery time, comparable to the pulse duration. This enables high duty cycle pulse trains and bursts. The fast recovery is achieved by a passively self gated charging of the pulse circuit.

### BACKGROUND OF THE INVENTION

1. Field of the Invention

The present invention relates generally to electrical pulse generation, and more particularly optical pulse generation by driving current pulses through a laser diode.

One application is within seeding of high power amplifiers, e.g. fiber optical amplifiers. This find application in master oscillator power amplifier laser systems.

The advantage of the disclosed pulse drive technique is its fast recovery time which among other things enable high duty cycle pulse bursts.

2. Description of Related Art

A widely used method for generating short i.e. less than a few tens of ns (1E-9 seconds) current pulse through a load, often a laser diode rely on fast discharge of a capacitor coupled to the laser diode. Using a small capacitance value on the order of 100 pF (1E-10 Farads) gives a pulse spike with good immunity to impedance mismatch. This is often used for driving large junction laser diodes to peak powers much above CW average power rating, i.e. several A (Ampere) current peaks.

In the conventional capacitor discharge pulse drive arrangement, see FIG. 1 the capacitor 104 is charged through a large value resistor 103 such that current through the charge path 108 from the supply rail 102 is negligible compared to that from the capacitor 104 positive (+) terminal which is what causes the current through the laser diode 106 when the fast discharge switch 101 is conducting to the lower supply rail 107 connected to the laser diode anode via the supply rail, 107 and 109 being at the same potential.

An electrical power supply means may in general be said to have a positive rail, also named positive pole or terminal, or just supply rail. For direct current to flow the power supply means must in addition have a negative rail, pole or terminal which in many cases is at the system ground potential.

FIG. 2 show the voltage evolution in trace a at the positive (+) terminal of capacitor 104, and the resulting current through the laser diode 106 is shown in trace b. At timing instance t1 the switch 101 is brought from open circuit to conducting state. The voltage on the capacitor 104 drops abruptly causing the negative terminal (−) to swing negative, with a notch (not shown) below the negative supply rail. This drives a forward current through the laser diode 106 as illustrated in trace b. The switch is in conduction state from time instance t1 to time instance t2 where it is brought in open circuit i.e. non conduction state. The positive side (+) of the capacitor 104 is charged through the resistor 103 in the time t2 to t3. The charge time, also called recovery time, sets the minimum pulse repetition period (T). The value of the resistor 103 needs to be large compared to the ON-resistance of the switch 101 for any voltage drop on the pulse forming capacitor 104 and resistor 105 to develop. As a consequence recharge time (t3-t2) is long leading to a minimum pulse repetition period which is long compared to the current pulsewidth. Such drivers are currently used for ns (1E-9 seconds) pulsewidths and ms (1E-3 seconds) pulse repetition period. With typical values for charge resistors on the order of 1K (1000 ohms), and capacitor 104 with capacitance on the order of 100 pF (1E-10 Farads) with resistor 105 of value on the order of 1R (1 ohm). For higher pulse repetition rates, the same as shorter pulse repetition periods the circuit does not have enough time to fully charge the capacitor. This conventional drive circuit has been adequate in numerous applications utilizing high peak current at low duty cycle, defined as pulse width divided by pulse repetition period. The attainable duty cycle with such driver is up to around 0.001% (1E-5).

Other, well known current pulse drive circuits include those using direct modulation with avalanche or normal mode transistor drive. It can be AC or DC coupled, and employ active push-pull drive. In the direct modulation scheme the current pulse follow the electrical switching. Unlike the capacitive discharge, as described in detail above where the current pulse duration, pulsewidth is limited by the discharge of a capacitor.

It is possible to use push-pull drive in a capacitive charge and discharge circuit, but it would require sub ns timing control of the charge path gating, which additionally needs to be smooth and free from ringing which otherwise would drive ghost pulses following the intended pulse. The shortcomings in attainable duty cycle of the conventional capacitor discharge pulse drive circuit, and the serious design challenges of actively timed discharge and charge circuit impose is the background for the disclosed novel pulse drive circuit.

### SUMMARY OF THE INVENTION

The invention solves the shortcoming of the prior art by taking advantage of the capacitive discharge pulse circuit and providing a passively self gating switched charge part to significantly reduce the charge time.

FIG. 3 shows a block diagram illustrating the operation of the present invention. Comparing with the conventional capacitive discharge circuit in FIG. 1 the circuit of the invention replaces the charge resistor with a charge control circuit block 303. The charge control block is connected to the positive terminal of the capacitor 305 by a charge path 308 and additionally by a feedback connection 302. The functioning of the charge control of the invention is detailed in FIG. 4. The upper supply rail connection 401 is connected via a current limiting circuit means 402 to a switch 403. The charge current is supplied on the connection 408 and the charge voltage is sensed on line 404. The decision circuit block 405 compares the voltage with a threshold and communicates a signal representing the threshold crossing instance to a time delay means 406, which in turn communicates a delayed version of the instance via the connection 407 to the charge current switch 403. The switch commutes from open circuit state to conducting state upon reception of the delayed signal. In this way the charge control circuit block 303 exhibits a high impedance allowing the switch 301 to effect an abrupt voltage drop at the positive (+) terminal of the capacitor 305 producing a current spike through the pulse forming resistor 306 and the load illustrated as a laser diode 307. The charge control detects the voltage drop and commutes the switches 403 to its conducting state allowing current to flow in the charge path through the current limiter 402 connected via 401 to a supply rail. When the charge voltage, e.g. the supply rail voltage minus a diode drop is reached the charge switch 403 returns to its high resistance, OFF or open circuit state ready for the next trigger pulse.

The capacitor 305 is referred to as having a positive (+) terminal, the most relevant type of capacitor is ceramic capacitor which a priori is polarity undesignated. The terminal is referred to as positive (+) because it, inside the circuit must be charged to a higher potential than the other terminal of the same capacitor.

The power supply connected to the laser diode anode can be any well buffered supply rail 309 including the circuit ground.

The rapid charging is what enables the fast recovery and short pulse repetition periods. As illustrated in FIG. 5 the pulse circuit of the invention has an evolution of the voltage at the positive terminal (+) of capacitor 305, trace c in FIG. 5, which exhibits a fast drop with undershoot 501 at the time instance t1. After the time delay on the order of the pulse width the recharge starts (403 switched to conducting state), possibly while the switch 301 is still in the conducting state leading to the dynamic balance at the plateau 502. When switch 301 is brought to the non conducting state the voltage recovers rapidly following the curve segment 503 to reach the charge voltage smoothly, as the voltage difference driving the current approaches zero.

The switch 301 may be any electrical switching means which can be commuted between a conducting and a non conducting or open circuit state by a command signal 310. The conduction state may also be referred to as low resistance or ON state, while the non conducting state may be refereed to as high resistance or OFF state and may not necessarily provide galvanic isolation. Switching may also be referred ON-OFF gating action. The same comments apply to the switch 403 commanded by the signal 407. The most relevant switching means are MOSFET or bipolar junction transistors.

The current limiting means can be a current limiting diode, or a feature of other circuit elements in the path or it can be any of the well known current clamping or constant current circuit arrangements from the established art of electronics.

The limit level of the current limiter 402 can allow currents near the pulse current such that pulse trains with duty cycle near 50% can be produced. This, among other things enable new modes of operation where long pulses of several 100 ns (1E-7 seconds) can be replaced with a train of closely spaced short pulses. This allow spectral broadening arising from the short pulses modulation of high energy pulse trains.

The short pulsewith drive capability with fast recovery has particular value in master oscillator fiber power amplifier laser systems where it can suppress nonlinear scattering e.g. stimulated Brillouin Scattering in the power amplifier. The high peak power of the short pulses are also advantageous in nonlinear frequency conversion, e.g. by four photon mixing of the laser output, directly from the laser diode or after power amplification.

Other applications include communications and coding of pulse bursts for laser ranging, for example for distance ambiguity resolution.

### BRIEF DESCRIPTION OF THE DRAWINGS

For a more complete understanding of the present invention, and the advantage it brings reference is now made to the ensuing description taken in connection with the accompanying drawings, briefly described as follows:

FIG. 1 Simplified schematic diagram of prior art capacitor discharge pulse driver.

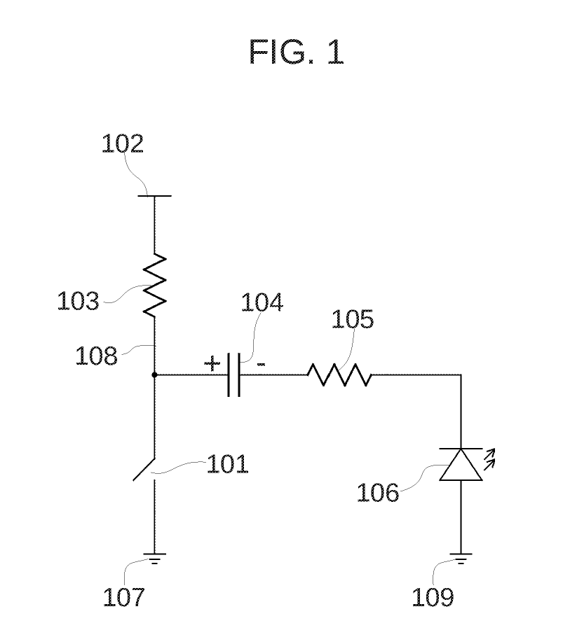

FIG. 2 Waveform graphs illustrating prior art charge cycle.

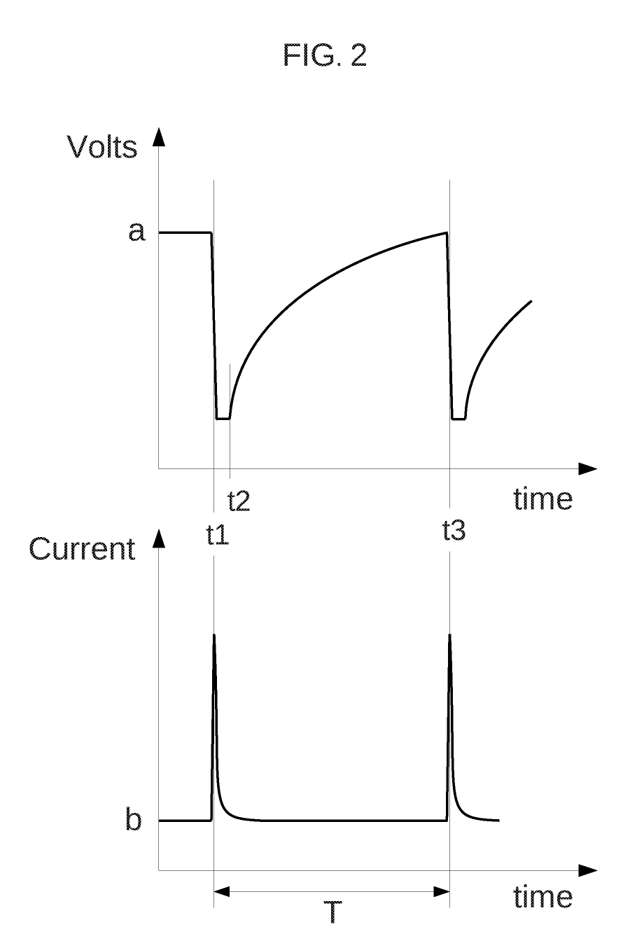

FIG. 3 Simplified schematic of the invention.

FIG. 4 Detailed block diagram of the charge control of the invention.

FIG. 5 Waveform graphs illustrating the charge cycle in the pulse driver of the present invention.

FIG. 6 Process flow chart of the method of the invention

FIG. 7 Circuit diagram of exemplary embodiment of the invention.

FIG. 8 Circuit diagram of preferred fully featured embodiment of the invention.

FIG. 9 Illustrative waveforms from the operation of the preferred fully featured embodiment of the invention.

FIG. 10 Illustrates use of inductive boost to produce pulse train with increasing peak level.

### DETAILED DESCRIPTION OF EMBODIMENTS

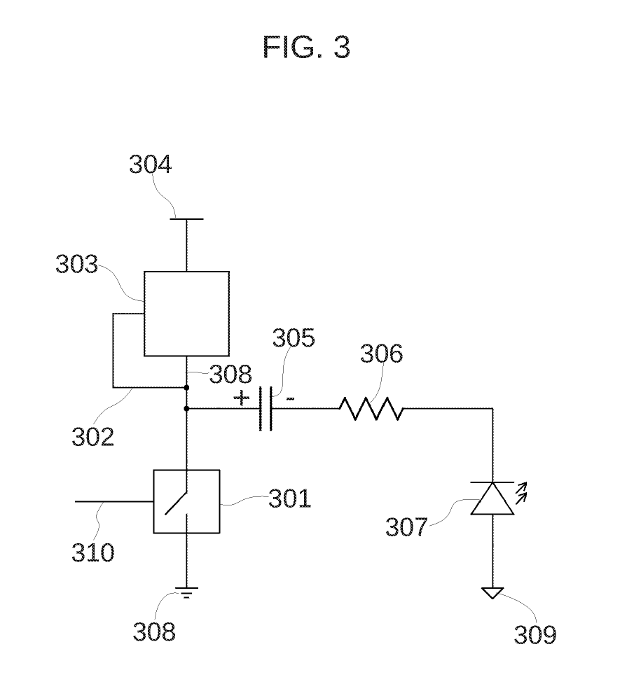

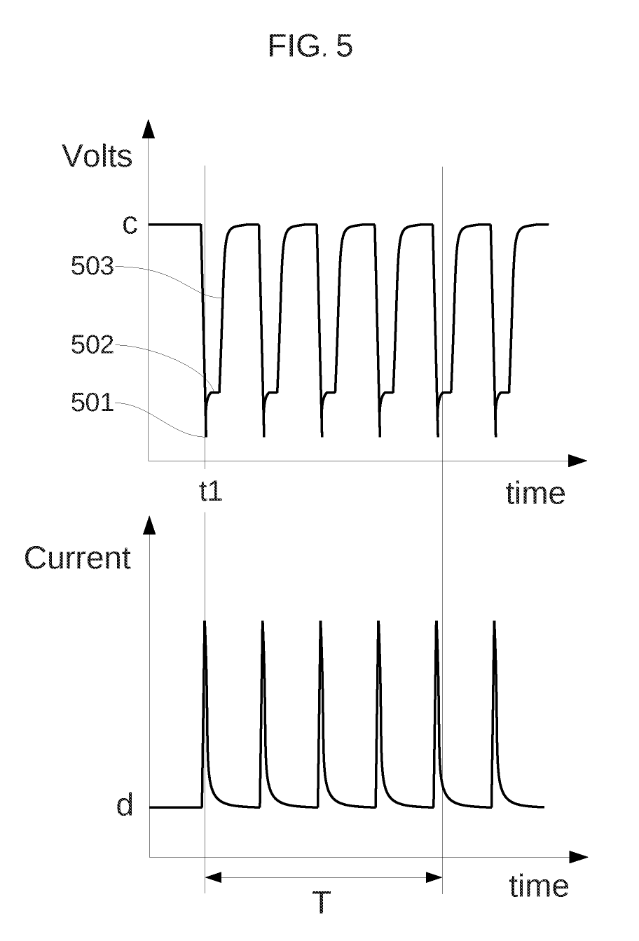

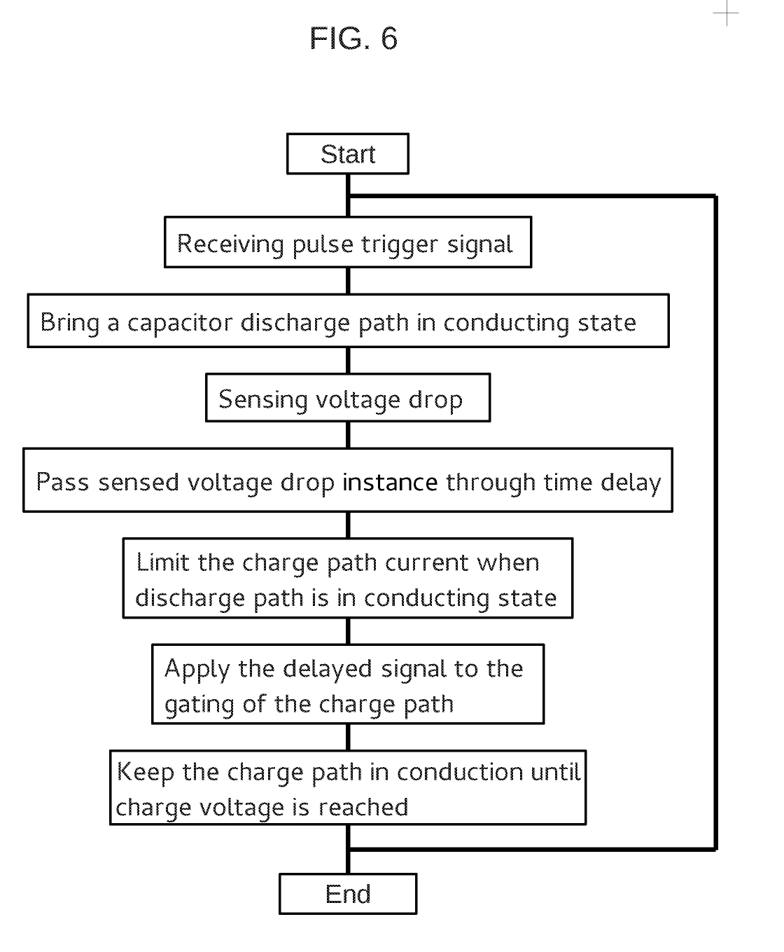

Further features and advantages of the invention as well as the structure and operation of exemplary embodiments of the invention are described in detail below, with reference to the accompanying FIGS. 3-10, wherein reference numerals have the FIG. number as the leading number.

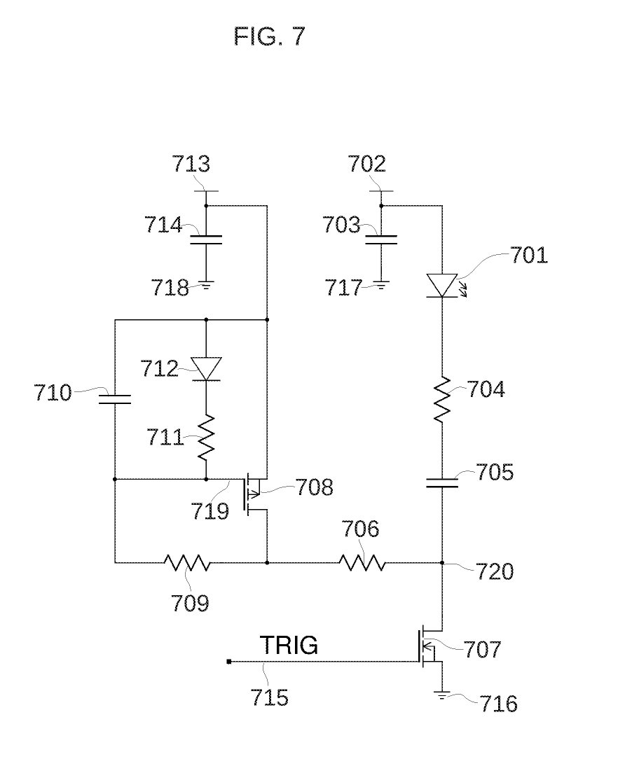

One exemplary embodiment of the present invention is illustrated in FIG. 7. A capacitive discharge pulse circuit comprises the capacitor 705, pulse forming resistor 704 and the laser diode supply 702, which is buffered to ground 717 by the decoupling capacitor 703. By switching the N-type MOSFET transistor 707 to its ON-state by driving the TRIG signal line 715 high, the falling voltage edge on the capacitor 705 drives a forward current spike through the laser diode load 701. The capacitor recharge circuit of the invention is embodied by the P-channel MOSFET 708 as switching and current limiting element and the delay element formed by the resistors 706 and 709 in combination with the capacitor 710 and the gate capacitance of the P-channel MOSFET. The gate 719 of the P-channel MOSFET is biased to the supply rail 713 with the pull up resistor 711 and the diode 712. The function of diode 712 is to match the bias voltage to the source to drain voltage drop of the P-channel MOSFET 708. With no pulse trigger, i.e. TRIG line 715 is low, the transistor 707 is OFF, in this state the gate voltage of the P-channel MOSFET is pulled to the supply rail 713 and the transistor 708 is in the OFF state. When a pulse trigger signal is applied as a rising edge from low to high on line 715 to the gate of the N-channel MOSFET 707 it goes from OFF state to ON state with a low, on the order of 1 R (1 ohm) on resistance. This causes the drain voltage (line 720) to drop abruptly since at this instance the connection to the supply rail 713 is switched to its OFF state and the charge path connected to the capacitor 705 via the resistor 706 exhibits a high impedance. The falling edge of the voltage at 720 is what caused the voltage on the capacitor 705 to drop and drive a current through the laser diode 701. The voltage drop also discharge the gate of the P-channel MOSFET 708, labeled 719 but at a rate set by the resistor 709 and 706. When the gate voltage at 708 reaches the switching voltage of the transistor, the supply rail 713 voltage plus the Gate Threshold Voltage (VGSth typically around −2 V) the charge path switch transistor 708 will go into its conducting ON state, exhibiting low impedance for the recharge. The transistor 708 will limit the charge current since it has a finite ON-State Drain Current on the order of 1 A (1 Ampere). When the TRIG signal 715 is brought low the transistor 707 goes to its OFF state and the capacitor 705 charges through the P-channel transistor 708. The drain to gate connection via the resistor 709 assures that the transistor 708 switches to its OFF state when the charge voltage reaches the switching voltage of the transistor. The pull up resistor 711 allow a designed balance between switch on delay set mainly by the resistor 709 and switch-off response set by the combined effect of resistor 709 and 711. The resistor 706 assures that the charge voltage is reached smoothly without overshoot. The described charge cycle is now returned to the state where the pulse driver is ready to receive the next rising edge on TRIG 715 commanding the firing of another pulse.

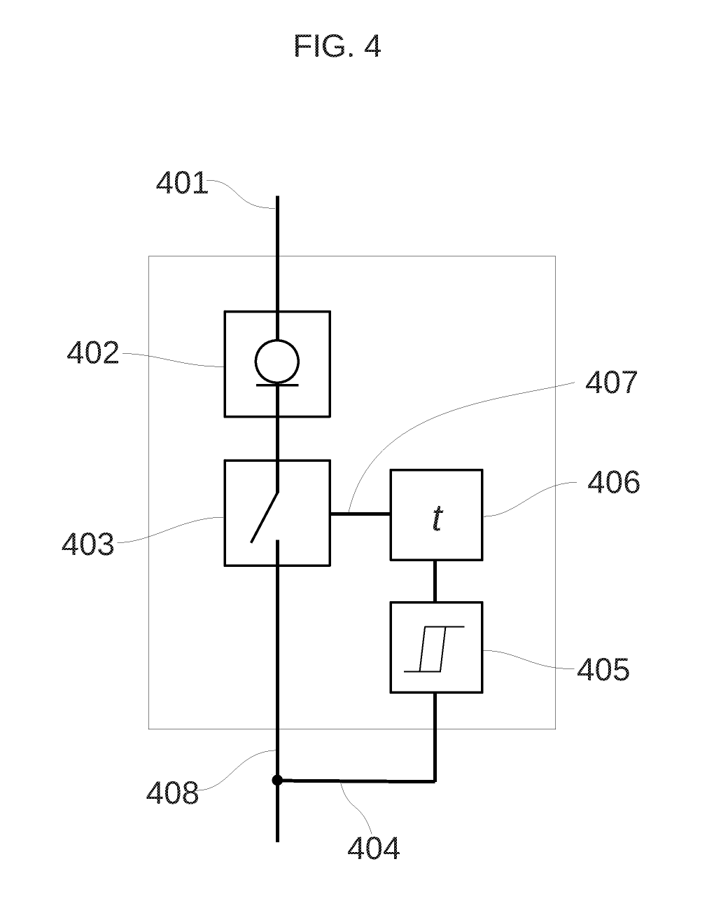

It is noted that the single element, the P-channel MOSFET 708 embodies the functions of current limiter 402 in FIG. 4, charge path switch 403 and voltage threshold crossing instance detection 405. The time delay 406 is embodied by the resistor capacitor network dominated by resistor 709 and capacitor 710 and MOSFET gate capacitance of 708.

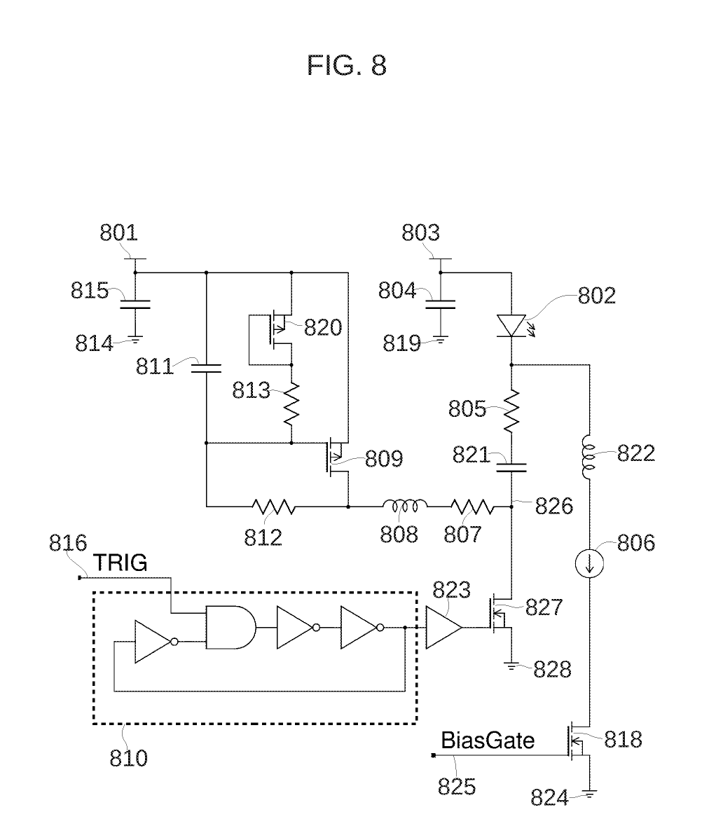

The more elaborated embodiment of FIG. 8 adds some features important for the practical utilization of the invention. A capacitive discharge sub-circuit is embodied by the capacitor 821 and N-channel MOSFET 827 which can be an RF Power Field Effect Transistor for fast switching. The discharge of 821 drives a current spike through the laser diode load 802 via the pulse forming resistor 805 from the supply rail 803 buffered by the capacitor 804 to ground 819.

The supply rail 803 can be at any voltage or at the ground level. The power supply of the preferred embodiment has the ground terminals 819 and 828 connected with low impedance as they close the fast pulse discharge path around the capacitor 821. The ground terminal 824 is at the same average potential, but may have transient isolation, e.g. a ferrite bead on its connection to 828. The potential of the supply rail 801 must be above that of terminal 828 for the charging and discharging cycle to take place. The preferred embodiment has the supply rails 801 and 803 at a high voltage and separate decoupling capacitor banks 815 and 804.

The pulse forming resistor 805 acts together with the capacitance value of 821 to set the pulse duration, e.g. large component values gives longer pulse duration.

The branch comprising the bias isolation inductor coil 822 and current sink 806, e.g. embodied by a current limiting diode, and the N-channel transistor 818, allow a small bias current through the laser diode to be turned ON and OFF. Some laser diodes of interest may gainswitch with an optical output pulsewidth much smaller than the applied current spike. To control, among other things this phenomenon a pre-bias of the laser diode is useful.

The pulse trigger input TRIG 816 connects to a logic gate oscillator 810. This allow a slow pulse trigger signal on 816 to set the duration of a pulse train, modulating the pulse duration into individual pulses at the oscillation frequency of the gated oscillator 810.

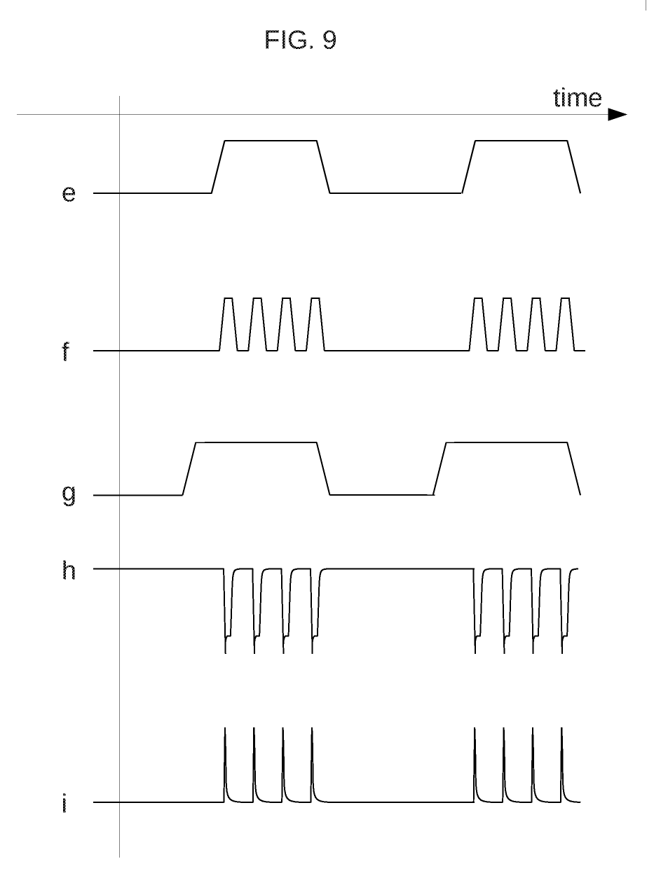

FIG. 9 shows typical timing diagrams for the different signals. Trace e is the pulse trigger, or pulse duration signal applied to TRIG 816, this signal gates the oscillator which supplies the oscillator signal f to the buffer 823. A bias gating signal, trace g is independently applied to the BiasGate line 825 control to pre-bias the laser diode before the current pulses, triggered by each rising edge of the oscillator signal f, arrive. The voltage on the capacitor 821 at 826 is shown in trace h, it drops with a fast falling edge, producing the current pulses shown in trace i, at the rising edge of the signal f and recovers as the capacitor 821 recharges through the charge control embodied by the charge switching P-channel transistor 809, with its MOSFET gate biased by the diode coupled P-channel transistor 820 and resistor 813.

A diode coupled transistor is used to match the transistor source to drain voltage drop of 809 across operating temperatures.

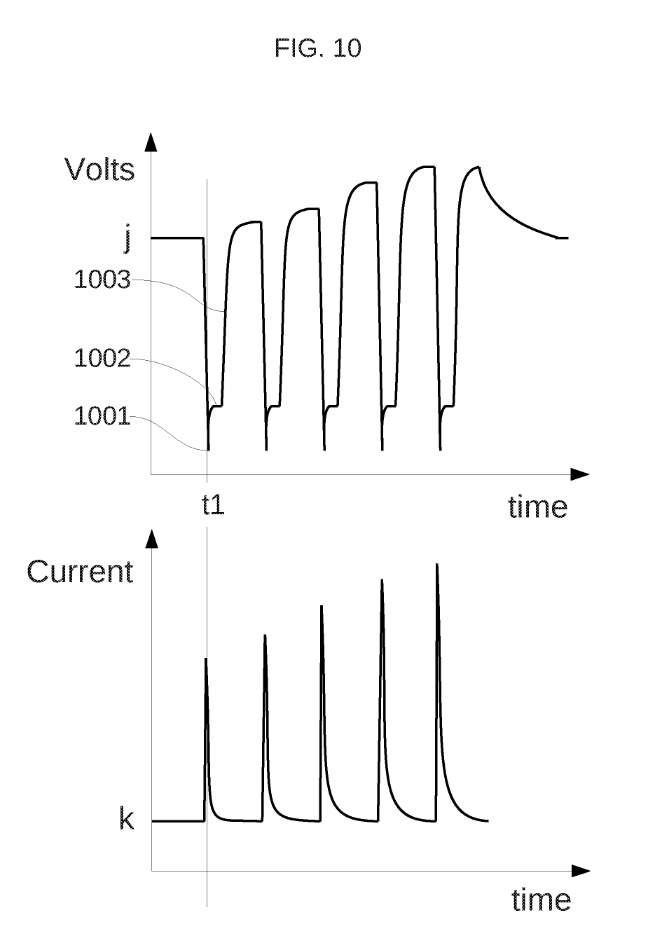

The inductor coil 808 has two main functions, first it adds to the impedance of the resistors 812 and 807 giving delay in the switching of 809, second it gives an inductive voltage boost, swinging the voltage at 826 higher than that at the supply rail 801 when the transistor 827 is turned OFF. This action is illustrated in FIG. 10 where trace j represent the voltage at 826. The pulse by pulse increased in voltage for each pulse in the pulse train gives the effect of increasing pulse peak current as shown in trace k. The peak power will settle at a dynamic equilibrium after some pulses.

The increase of peak power from the level of the first pulses in a pulse burst is an advantage for laser diode output pulse trains which are to be amplified in optical amplifiers exhibiting gain saturation. In such amplifiers the first few pulses will experience higher gain than subsequent pulses. The ramping of the laser diode pulse peak current and thus peak optical output from the laser diode will counter act the gain saturation such that the amplified pulse train will exit the amplifier with leveled peak powers. This so called predistortion, preemphasis or first pulse suppression may be use in combination with known optical domain predistortion techniques to enhance the performance e.g. it may be used in arrangements including an optical saturable absorber means between the pulse drive laser diodes output and the optical amplifier input.

The embodiments in FIGS. 7 and 8 have the simplicity of letting a single element, 709 and 809 respectively, perform the voltage threshold crossing detection, current limiting and charge switching.

It is obvious that several elements could be combined to performed the functionalists of the block diagram in FIG. 4. A compactor integrated circuit (IC) or operational amplifier could be used to detect the voltage drop, a digital delay line or RC (resistor capacitor) based timer IC could perform the timing delay and several switch elements exist which could implement the charge path switching. It also follows from the description of the invention, that a functioning circuit can be constructed by using only part of the functional blocks. In particular a current limiter alone, i.e. no switching element in the charge path, would be less than optimal but would work. Likewise the current limiter can be omitted if the time delay for the switching ON, of the recharge is longer than the ON-time of the pulse switch.

The invention has been described above using specific embodiments for the purpose of illustration. It will be readily apparent to one of ordinary skills in the art, however that the principles of the invention can be embodied in other ways, for example other transistor types that the MOSFET may be used and current limitation can be implemented in a number of well know ways other than a current limiting diode, oscillator circuits may be constructed in ways alternative to the mentioned logic gate oscillator, for example utilizing crystal oscillators or digital counters based on a higher frequency clock. The oscillator may be always oscillating and its output gated or the gating action may turn the oscillator ON and OFF. The laser diode pre-bias arrangement may be connected in alternative ways providing a limited current low through the laser diode and include a switch or omit it. Therefore the invention should not be regarded as being limited in scope to the specific embodiments disclosed herein, but instead as being fully commensurate in scope with the following claims.

What is claimed is:

1. Pulse driver circuit means for providing high current pulses of short duration through a load having a first and second terminal, comprising:
a power supply means;
a capacitor having a first and second terminal;
a first transistor configured to receive a pulse trigger signal on its gate;
a second transistor of P-channel type, the source of which is connected to the power supply means and the drain is connected to the first terminal of the capacitor and via a resistive connection to the gate of said second P-channel transistor. The second terminal of the capacitor is connected to the first terminal of the load. The second terminal of the load being connected to the source of said first transistor by a connection exhibiting low impedance at high frequency.

2. A system in which the drive circuit of claim 1 has, as its load a laser diode and the output is optical pulses.

3. A method comprising the steps of:
Receiving a pulse trigger signal;
Bring a capacitor discharge path in conducting state;
Sensing voltage drop on the capacitor;
Pass sensed voltage drop time instance through a time delay;
Limit the current from a power supply means to the capacitor;
Apply the delayed voltage drop instance signal to a switch means on the charge path;
Keep the charge path in conduction until charge voltage is reached, then bring it in open circuit state.

4. An electrical current pulse driver circuit apparatus, comprising:
a capacitor;
a first switch configured to receive a pulse commanding signal and to discharge the capacitor;
a power supply; and
a switching capacitor charging circuit connected between the power supply and the capacitor, the charging circuit switching the charging current to the capacitor in dependence of the charge on the capacitor.

5. A pulse driver of claim 4 incorporating a gated oscillator with its output alternating the first switch.

6. A laser diode pulse drive circuit having a capacitor with one terminal connected to a laser diodes cathode and the other, positive terminal connected to a first switching element which in its conducing state establish a low resistance current path through it to the laser diodes anode, further a circuit configured to sens the voltage on said capacitors positive terminal and a second switch activated in dependence of the sensed voltage, bringing said second switch in conduction to a power supply positive pole upon a configured time delay and out of conducting state when the sensed voltage crosses a threshold.

7. A laser diode pulse drive circuit of claim 6 incorporating an inductive coil serially connected in the conduction path between the capacitor positive terminal and the second switch.

8. A laser pulse driver of claim 6, incorporating a laser diode biasing branch from the laser diode cathode to the power supply negative pole through a current limiting means.

9. A laser pulse driver of claim 6 incorporating a laser diode biasing network connecting a power supply means to the laser diode through a current limiting means and a switch.

10. An optical master oscillator power amplifier system, comprising;
at least one fiber optical amplifier;
a laser diode with its output connected to said optical amplifier, the laser diode being pulse driven by the driver of claim 6.
